(19) United States
(12) Patent Application Publication
(10) Pub. No.: US 2015/0181761 A1
(43) Pub. Date: Jun. 25, 2015

(54) HEAT DISSIPATION APPARATUS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: CHAO LIU, Wuhan (CN); ZHI-PING WU, Wuhan (CN); SHENG-GUI LIU, Wuhan (CN)

(21) Appl. No.: 14/523,274

(22) Filed: Oct. 24, 2014

(30) Foreign Application Priority Data
Dec. 20, 2013 (CN) 201310704656.7

(51) Int. Cl. H05K 7/20

(52) U.S. Cl. CPC H05K 7/20154; H05K 7/2039

(57) ABSTRACT

A heat dissipation apparatus includes a heat absorption piece, a attachment bracket, a heat dissipation device, and a heat transfer member. The heat absorption piece is configured to make contact with an electronic element electrically connected to a circuit board, to absorb heat generated by the electronic element. The attachment bracket is attached to the circuit board and defines a first groove configured to receive the heat absorption piece. A first part of the heat transfer member touches the heat absorption piece. A second part of the heat transfer member touches the heat dissipation device. The heat transfer member is configured to transfer the heat of the heat absorption piece to the second part of the heat transfer member to be dissipated by the heat dissipation device.

### CROSS-REFERENCE TO RELATED APPLICATIONS

This application claims priority to Chinese Patent Application No. 201310704656.7 filed on Dec. 20, 2013, the contents of which are incorporated by reference herein.

### FIELD

The present disclosure relates to heat dissipation.

### BACKGROUND

Electronic device includes a circuit board and a number of electronic components electrically connected on the circuit board. A fan is employed in the electronic device to dissipate heat generated by the electronic components.

### BRIEF DESCRIPTION OF THE DRAWINGS

Implementations of the present technology will now be described, by way of example only, with reference to the attached figures.

FIG. 1 is an exploded isometric view of a heat dissipation apparatus according to an exemplary embodiment.

FIG. 2 is an exploded isometric view of a attachment bracket of the heat dissipation apparatus of FIG. 1.

FIG. 3 is similar to FIG. 2, but viewed from another angle.

FIG. 4 is an isometric view of the attachment bracket with a heat absorption piece in place.

FIG. 5 is an isometric view of a heat dissipation apparatus of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising” means “including, but not necessarily limited to”; it specifically indicates open-ended inclusion or membership in a so-described combination, group, series, and the like.

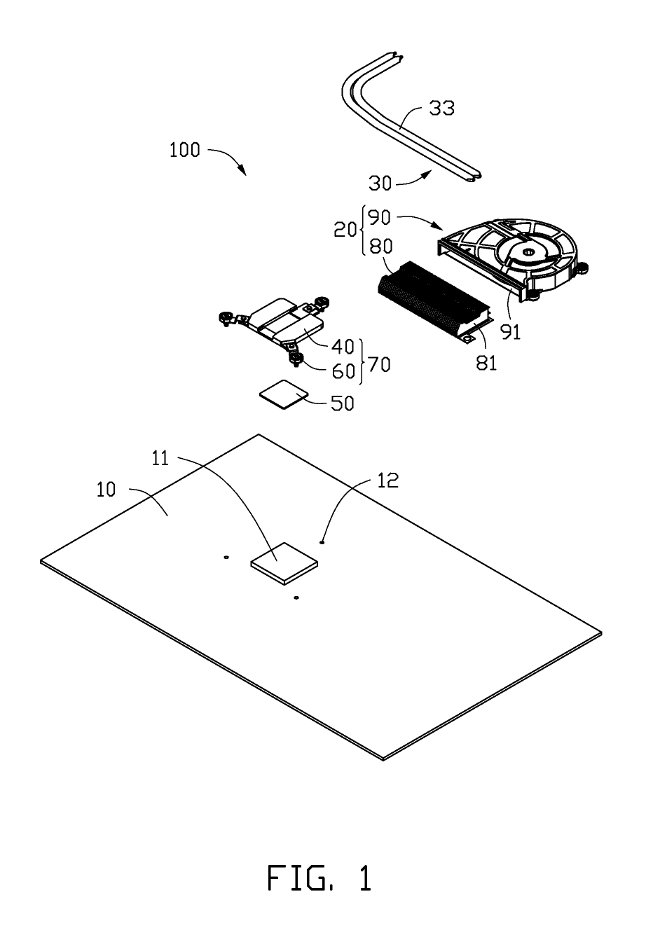

FIG. 1 illustrates a heat dissipation apparatus 100 employed on a circuit board 10. An electronic element 11 is electrically connected to a circuit board 10. The heat dissipation apparatus 100 is configured to dissipate heat generated by the electronic element 11. The heat dissipation apparatus 100 includes a heat absorption piece 50, an attachment bracket 70, a heat transfer member 30, and a heat dissipation device 20.

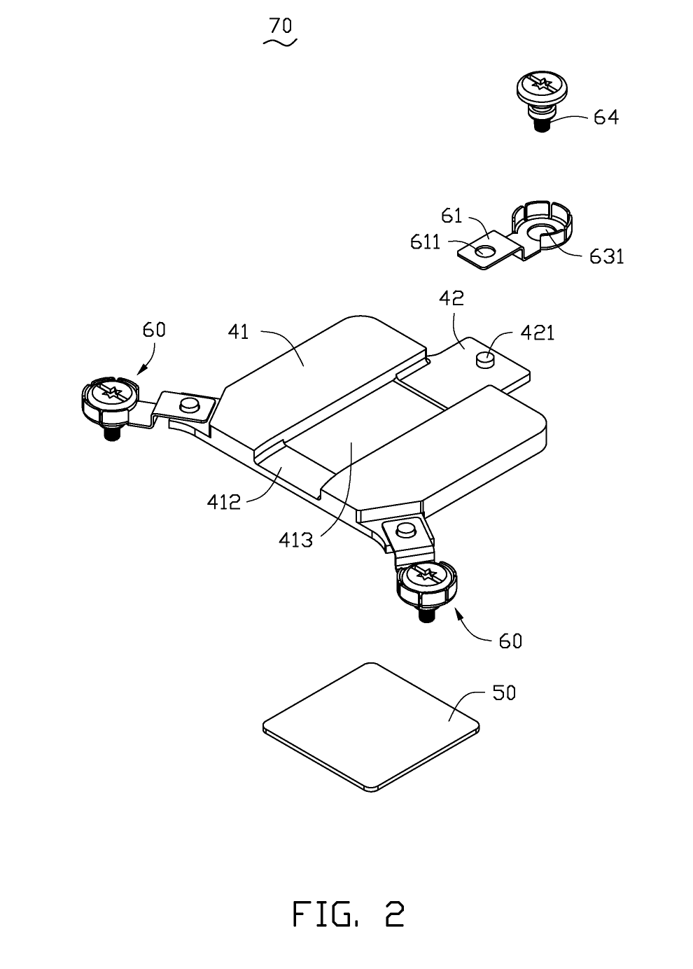

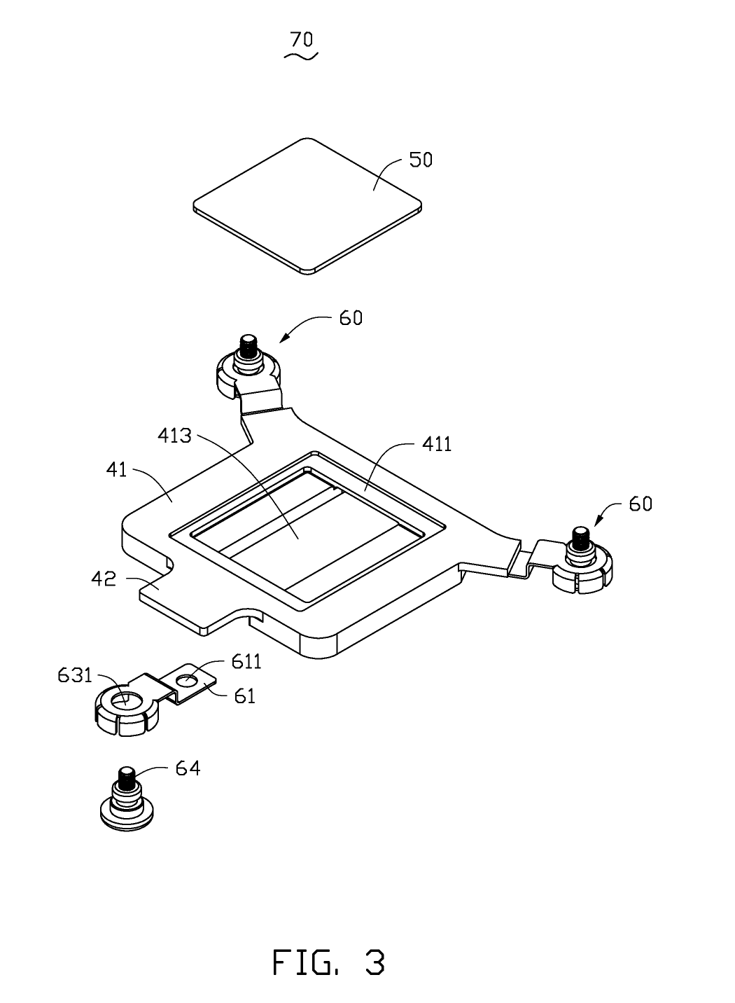

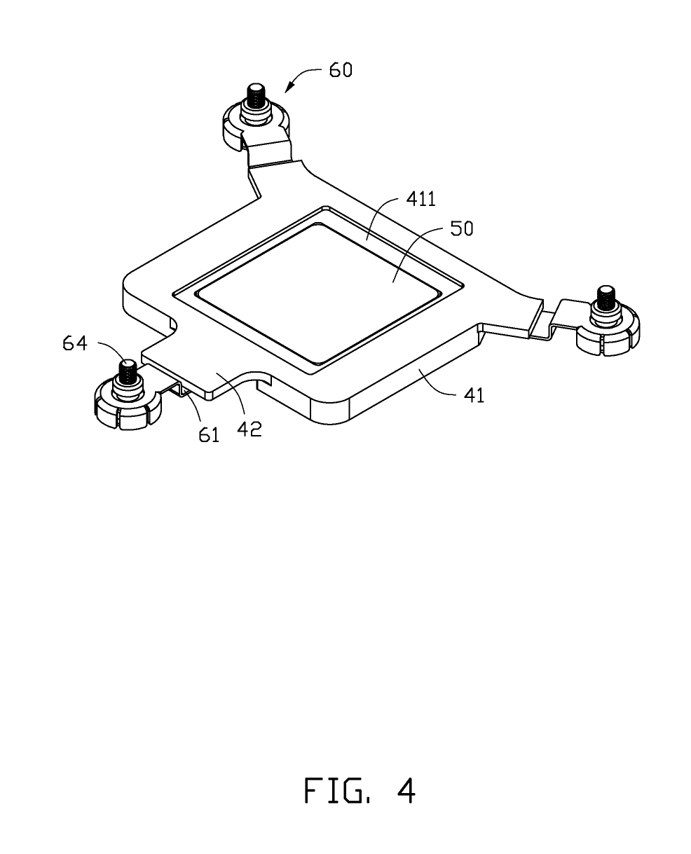

Further referring to FIG. 2, the attachment bracket 70 includes a fixing plate 40 and three fixing members 60. The fixing plate 40 includes a base plate 42. Referring to FIG. 3, a bottom surface of the base plate 42 defines a first groove 411. A top surface of the base plate 42 defines a second groove 413 communicating with the first groove 411. A size of the first groove 411 is greater than that of the second groove 413. Referring to FIG. 4, the first groove 411 is configured to receive the electronic element 11. The second groove 413 is configured to receive the heat absorption piece 50. The heat absorption piece 50 is positioned on the electronic element 11. A surface of the heat absorption piece 50 away from the electronic element 11 and the top surface of the base plate 42 are on the same plane. Three protrusions 421 protrude from the top surface of the base plate 42.

A first end of the fixing member 60 defines a through hole 611. A second end of the fixing member 60 includes a fastening portion 64. The three through holes 611 are configured to receive the three protrusions 421. The circuit board 10 defines three fixing holes 12. The three fastening portions 64 are attached in the three fixing holes 12 to fix the fixing plate 40 on the electronic element 11. In at least one embodiment, the fixing member 60 includes a fixing piece 61 and a bolt 64. The through hole 611 is defined on the fixing piece 61. The fixing piece 61 further defines an installation hole 631. The fixing hole 12 is a threaded hole. The three bolts 64 pass through the three installation holes 631 to fasten in the three threaded holes. The fixing piece 61 is “Z” shaped and is elastic. An angle between each two fixing members 60 is 120 degrees.

The fixing plate 40 further includes two restriction members 41. The two restriction members 41 protrude from the top surface of the base plate 42. The two restriction members 41 are opposite each other and define a receiving groove 412 between the two restriction members 41. The receiving groove 412 communicates with the second groove 413. A part of the heat transfer member 30 is received in the receiving groove 412 and touches the heat absorption member 50.

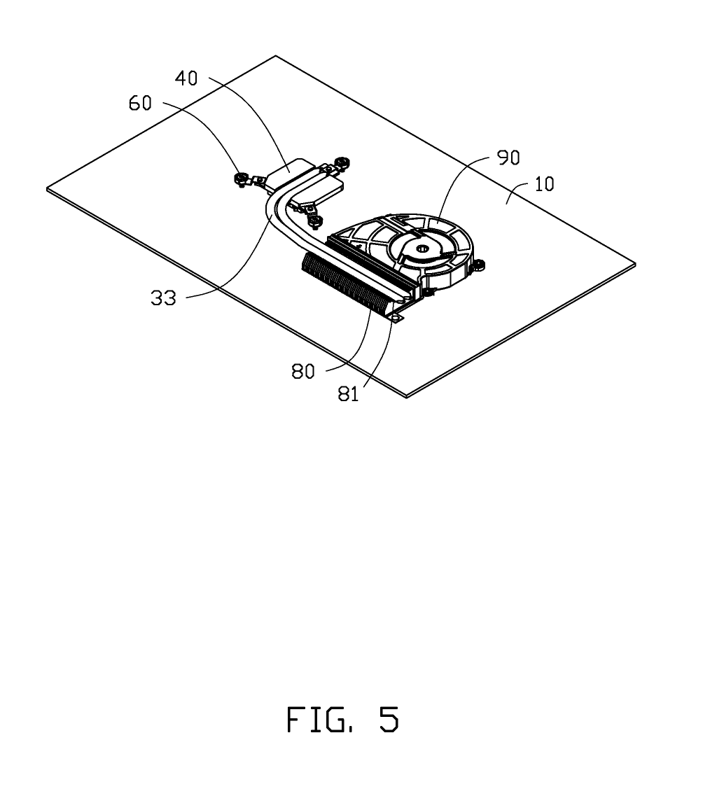

Also referring FIG. 1, the heat dissipation device 20 includes a fin group 80 and a fan 90. The fin group 80 defines a heat dissipation groove 81. The fan 90 defines an air outlet 91. The fin group 80 is attached to the fan 90 and faces the air outlet 91. Referring to FIG. 5, another part of the heat transfer member 30 is received in the heat dissipation groove 81. The heat generated by the electronic element 11 is absorbed by the heat absorption piece 50 and is then transferred to the fin group 80 by the heat transfer member 30 to be taken away by the fan 90. Thus, the electronic element 11 is cooled by the heat dissipation apparatus 100. In the embodiment, the heat transfer member 30 includes two bent heat transfer tubes 33.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including, the full extent established by the broad general meaning of the terms used in the claims.

What is claimed is:

1. An electronic element heat dissipating apparatus comprising:
a heat absorption piece;
an attachment bracket to hold the heat absorption piece in contact with the electronic element;
a heat transfer member in contact with the heat absorption piece;
a heat dissipation device in contact with the heat transfer member;
wherein, the attachment bracket defines a first groove configured to receive the heat absorption piece and is attachable to circuit board electronically connected to the electronic element;
wherein, the heat transfer member is configured to transfer heat from the heat absorption member to the heat dissipation device with a first part of the heat transfer member in contact with the heat absorption member and a second part of the heat transfer member in contact with the heat dissipation device.

2. The heat dissipation apparatus as claimed in claim 1, wherein the attachment bracket defines a second groove, the second groove communicates with the first groove and configured to receive the electronic element.

3. The heat dissipation apparatus as claimed in claim 1, wherein the attachment bracket comprises a base plate and two restriction members, the base plate defines the first groove, a receiving groove is defined between the two restriction members, the receiving groove is communicated with the first groove and configured to receive the part of the heat transfer member.

4. The heat dissipation apparatus as claimed in claim 3, wherein three protrusions protrude from the base plate, the attachment bracket further comprises three fixing members, a first end defines a through hole, the three protrusions are received in the three through holes.

5. The heat dissipation apparatus as claimed in claim 4, wherein the circuit board defines three fixing holes, a second end of the fixing member comprises a fastening portion, the three fastening portions are received in the three fixing holes.

6. The heat dissipation apparatus as claimed in claim 5, wherein the fixing member comprises an fixing piece and a bolt, the through hole is defined on the fixing piece, the fixing piece further defines an installation hole, the fixing hole is a threaded hole, the three bolts pass through the three installation holes to fasten in the three threaded holes.

7. The heat dissipation apparatus as claimed in claim 6, wherein the fixing piece is elastic.

8. The heat dissipation apparatus as claimed in claim 6, wherein the fixing piece is Z shaped.

9. The heat dissipation apparatus as claimed in claim 1, wherein the heat dissipation device comprises a fin group and a fan, the fin group is adjacent to and faces an air outlet of the fan, the another part of the heat transfer member touches the fin group.

10. The heat dissipation apparatus as claimed in claim 9, wherein the fin group defines a receiving groove, the another part of the heat transfer member is received in the receiving groove.

11. The heat dissipation apparatus as claimed in claim 1, where in the heat transfer member comprises a plurality of heat transfer tube.

12. The heat dissipation apparatus as claimed in claim 1, where in the heat transfer member is bended.

13. An electronic element heat dissipating apparatus comprising:
a heat absorption piece;
an attachment bracket to hold the heat absorption piece in heat-transferable contact with the electronic element;
a heat transfer member in heat-transferable contact with the heat absorption piece;
a heat dissipation device in heat-transferable contact with the heat transfer member;
wherein, the attachment bracket defines a first groove configured to receive the heat absorption piece and is attachable to circuit board electronically connected to the electronic element;
wherein, the heat transfer member is configured to transfer heat from the heat absorption member to the heat dissipation device with a first part of the heat transfer member in heat-transferable contact with the heat absorption member and a second part of the heat transfer member in heat-transferable contact with the heat dissipation device.

14. The heat dissipation apparatus as claimed in claim 13, wherein the attachment bracket defines a second groove, the second groove communicates with the first groove and configured to receive the electronic element.

15. The heat dissipation apparatus as claimed in claim 14, wherein a size of the second groove is greater than that of the first groove.

16. The heat dissipation apparatus as claimed in claim 13, wherein the attachment bracket further comprises two restriction members, a receiving groove is defined between the two restriction members, the receiving groove is communicated with the first groove and configured to receive the part of the heat transfer member.

17. The heat dissipation apparatus as claimed in claim 13, wherein the attachment bracket further comprises three fixing members, an end of the fixing member is attached to the base plate, the other end of the fixing member is attached to the circuit board.

18. The heat dissipation apparatus as claimed in claim 17, wherein an angle between each two fixing members is 120 degrees.

19. The heat dissipation apparatus as claimed in claim 13, wherein the heat dissipation device comprises a fin group and a fan, the fin group is adjacent to and faces an air outlet of the fan, the another part of the heat transfer member touches the fin group.

20. The heat dissipation apparatus as claimed in claim 19, wherein the fin group defines a receiving groove, the another part of the heat transfer member is received in the receiving groove.
